(19) United States
(12) Patent Application Publication
(10) Pub. No.: US 2013/0126974 A1
(43) Pub. Date: May 23, 2013

(54) ELECTROSTATIC DISCHARGE PROTECTION CIRCUIT

(71) Applicants: Ying-Hsuan WANG, Yuanlin Township (TW); Fang-Mei CHAO, Taichung City (TW); Chia-Hsiang PAN, Hsinchu City (TW); Yung-Chih SHIH, Taichung City (TW)

(72) Inventors: Ying-Hsuan WANG, Yuanlin Township (TW); Fang-Mei CHAO, Taichung City (TW); Chia-Hsiang PAN, Hsinchu City (TW); Yung-Chih SHIH, Taichung City (TW)

(73) Assignee: UNITED MICROELECTRONICS CORPORATION, HSINCHU (TW)

(21) Appl. No.: 13/299,415

(22) Filed: Nov. 18, 2011

(51) Int. Cl. H01L 29/06

(52) U.S. Cl. 257/355; 257/E29.012

(57) ABSTRACT

An electrostatic discharge protection circuit is used in an integrated circuit with a first sub-circuit working with a first working voltage source and a second sub-circuit working with a second working voltage source lower than the first working voltage source. The electrostatic discharge protection circuit includes a first metal-oxide-semiconductor transistor of a first conductive type, having a drain thereof electrically connected to a pad of the integrated circuit, and gate, source and bulk thereof electrically connected to a bulk voltage; and a guard ring of the first conductive type, surrounding the first metal-oxide-semiconductor transistor of the first conductive type and coupled to the second working voltage source.

### FIELD OF THE INVENTION

The present invention relates to a metal-oxide-semiconductor (MOS) structure, and more particularly to a MOS transistor structure.

### BACKGROUND OF THE INVENTION

Nowadays, a circuit chip integrated therein both a power device subjected to high voltage or high current and an analog or digital circuit subjected to low voltage has replaced traditional bulky and expensive discrete circuits and become a mainstream in the art. For example, a lateral diffused MOSFET (LDMOS) is one of the MOS transistors that exhibit high voltage tolerance, and is thus applicable to a variety of functional circuits requiring high voltage tolerance, e.g. electrostatic discharge (ESD) protection circuit.

FIG. 1 schematically illustrates a functional block diagram of an ESD protection circuit. The high side LDNMOS 11 is placed between I/O pad 10 and Vdd, and the low side LDNMOS 12 is placed between I/O pad 10 and Vss.

MOS transistor structures exhibiting high voltage tolerance commonly include a parasitic bipolar junction transistor (BJT). Further in view of a CMOS manufacturing process applied for producing such MOS transistor structures, a P-N-P-N quadruple-layer structure is likely to occur. Once the circuit is operated under a condition that allows the P-N-P-N quadruple-layer structure constituted by the parasitic BJT to be conducted, short circuit might happen between Vdd and Vss or usually ground. Then the large current would damage devices. That is so-called “latch-up”. Latch-up is usually not significant in a manufacturing process involving large line width, but becomes serious with decreasing line width and conducting voltage of the parasitic BJT. Therefore, to prevent from latch-up is an important issue for IC designs.

### SUMMARY OF THE INVENTION

Therefore, the present invention provides a MOS transistor structure with diminished latch-up effect.

The present invention provides an electrostatic discharge protection circuit for use in an integrated circuit with a first sub-circuit coupled to a first working voltage source and a second sub-circuit coupled to a second working voltage source, wherein the second working voltage is lower than the first working voltage source. The electrostatic discharge protection circuit includes a first metal-oxide-semiconductor transistor of a first conductive type, having a drain thereof electrically connected to a pad of the integrated circuit, and gate, source and bulk thereof electrically connected to a bulk voltage; and a guard ring of the first conductive type, surrounding the first metal-oxide-semiconductor transistor of the first conductive type and coupled to the second working voltage source.

In an embodiment, the ESD protection circuit further includes a second metal-oxide-semiconductor transistor of the first conductive type, wherein the second metal-oxide-semiconductor transistor of the first conductive type has drain thereof electrically connected to the first working voltage source, and gate and source thereof electrically connected to the pad.

In an embodiment, the guard ring includes a high voltage N well region and a highly doped N-type region.

The first sub-circuit, for example, is a high voltage circuit and the second sub-circuit, for example, is a digital logic circuit.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic functional block diagram illustrating a typical ESD protection circuit;

FIG. 2 is a schematic diagram illustrating a MOS transistor structure surrounded by an n-type guard ring;

FIG. 3 is a functional block diagram schematically illustrating an ESD protection circuit comprising the MOS structure of FIG. 2;

FIG. 4 is a cross-sectional view of an LDNMOS applicable to the ESD protection circuit of FIG. 3;

FIG. 5 is a functional block diagram schematically illustrating a preferred embodiment of an ESD protection circuit comprising the MOS structure of FIG. 2; and

FIG. 6 is a cross-sectional view of an LDNMOS applicable to the ESD protection circuit of FIG. 5.

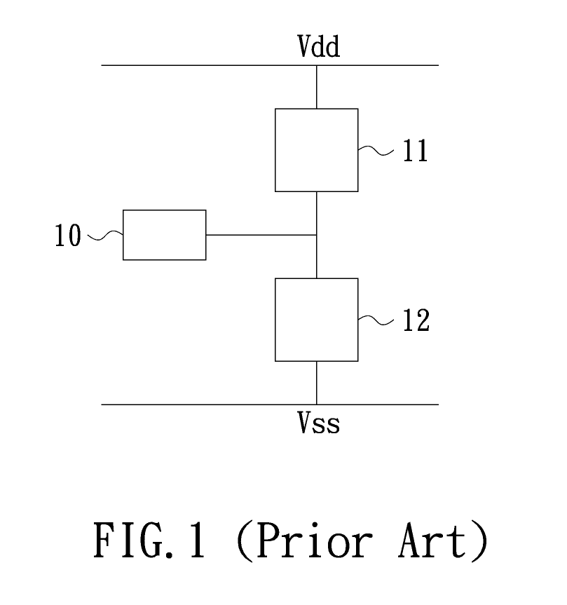

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

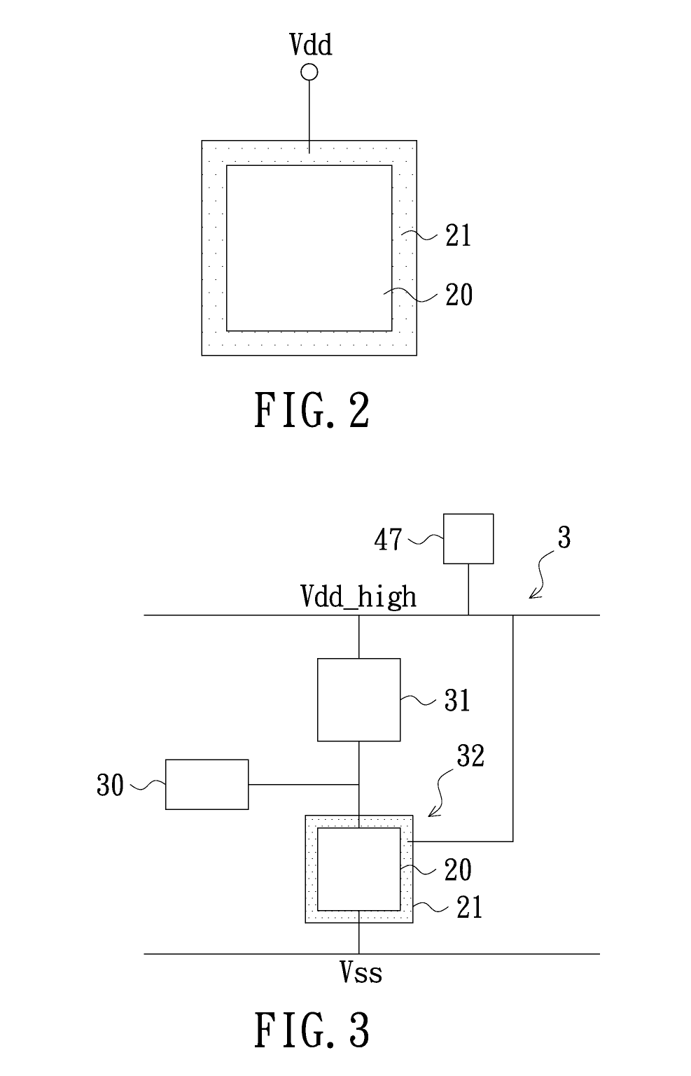

Please refer to FIG. 2. A MOS transistor structure exhibiting high voltage tolerance includes, in the central portion, an N-type MOSFET 20, e.g. a lateral diffused N-channel MOSFET (LDNMOS). For reducing latch-up, an N-type guard ring 21 is configured to surround the N-type MOSFET 20, and electrically connected to a voltage source Vdd.

An electrostatic discharge (ESD) protection circuit 3, having a functional block diagram as shown in FIG. 3, is disposed adjacent to an I/O pad 30, and mainly includes a high side LDNMOS 31 and a low side LDNMOS 32. The drain of the high side LDNMOS 31 are electrically connected to a high working voltage V_{dd}_{_{—}}_{high}, which is about 60 volts, and the gate and source are electrically connected to the I/O pad 30. The gate, source and bulk of the low side LDNMOS 32 are electrically connected to a bulk voltage Vss or usually grounded, and the drain is electrically connected to the I/O pad 30. The low side LDNMOS 32 is implemented with the N-type MOSFET 20 surrounded with the N-type guard ring 21 as shown in FIG. 2.

The ESD protection circuit 3 is commonly used in an integrated circuit 4 that includes a first sub-circuit 47 coupled to the high working voltage source V_{dd}_{_{—}}_{high} and a second sub-circuit 48 coupled to a low working voltage source V_{dd}_{_{—}}_{low}. Since the most available voltage source in the circuit is the 60-volt high voltage source V_{dd}_{_{—}}_{high}, the N-type guard ring 21 can be conveniently coupled to the high voltage source V_{dd-}_{_{—}}_{high} as well as the high-voltage sub-circuit 47. Accordingly, the latch-up effect can be minimized.

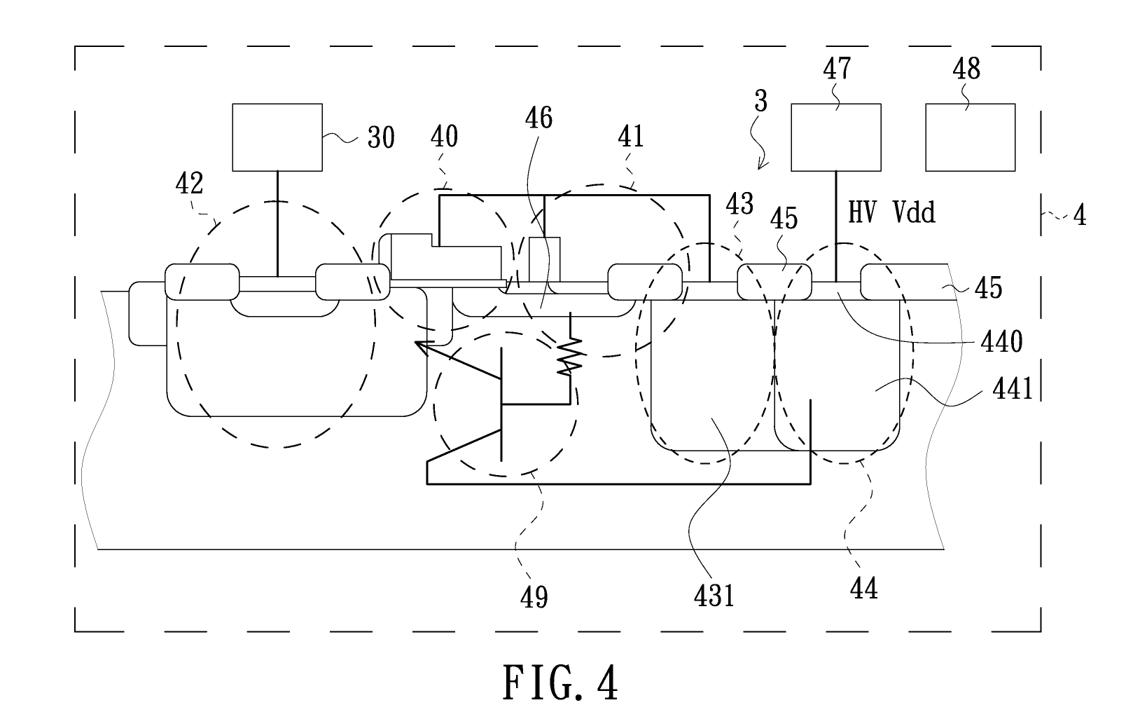

Referring to FIG. 4, a cross-sectional view of an LDNMOS applicable to the ESD protection circuit of FIG. 3 is schematically shown. The LDNMOS includes a gate structure 40, a source structure 41, a drain structure 42 and a bulk structure 43. A guard ring 44 surrounding the LDNMOS includes a high voltage N-well region 441 and a highly doped N-type region 440. Beside the guard ring 44, a shallow trench isolation (STI) structure 45 is formed. The gate structure 40, source structure 41 and bulk structure 43 are all electrically connected to Vss or grounded, the drain structure 42 is electrically connected to the I/O pad 30, and the guard ring 44 shares the high voltage V_{dd}_{_{—}}_{high} with the first sub-circuit 47, thereby constructing the ESD protection circuit 3. The first sub-circuit 47, for example, is a high voltage circuit.

It is found by way of a test that the ESD protection circuit 3 configured to have the N-type guard ring 44 coupled to the high voltage source exhibits diminished latch-up. Unfortunately, the ESD protection circuit 3 is at a risk of damage due to the reduction of the tolerance to a high voltage. For example, the tolerance of a common 60-volt LDNMOS, without the guard ring 44, to a current flow from the I/O pad 30 to the drain structure 42 is greater than 500 mA. In contrast, on the same conditions except the disposition of the guard ring 44, the tolerance to a current flow from the I/O pad 30 to the drain structure 42 is largely reduced to 109 mA. Thus a current flow having an intensity greater than 109 mA might burn the transistor out.

The reduction in current tolerance may be imputed to the use of the guard ring. When the negative current flow from the I/O pad 30 to the drain 42 is intense enough to turn on the NPN bipolar junction transistor (BJT) 49 consisting of the N-type drain structure 42, the P-type body structure 46 and the N-type guard ring 44, the PN junction between the high voltage N well 441 and the grounded P well 431 will be subject to a large amount of current due to the high voltage of the guard ring 44. The heat caused by the high power rate is likely to damage the device.

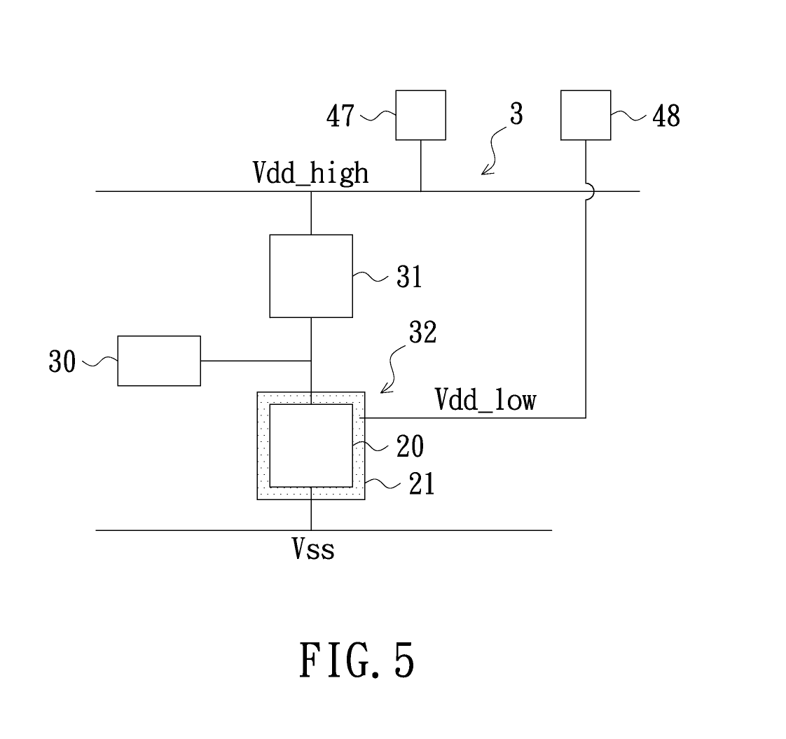

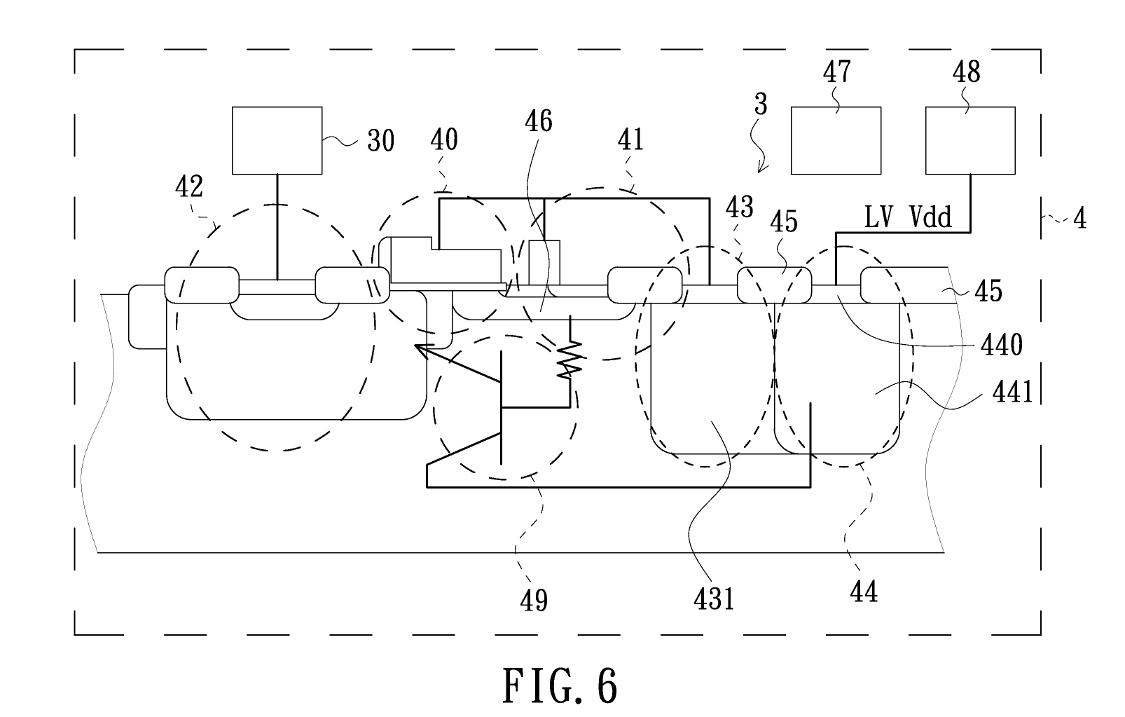

Therefore, in a preferred embodiment of the ESD protection circuit as illustrated in FIG. 5, the guard ring 21 is coupled to the low working voltage V_{dd}_{_{—}}_{low}, which the sub-circuit 48 is coupled to, instead of the high working voltage V_{dd}_{_{—}}_{hjgh}, which the sub-circuit 47 is coupled to. Furthermore, an LDNMOS which includes a gate structure 40, a source structure 41, a drain structure 42 and a bulk structure 43, as illustrated in FIG. 6, is applicable to the ESD protection circuit of FIG. 5. Likewise, the guard ring 44 surrounding the LDNMOS includes the high voltage N-well region 441 and highly doped N-type region 440, and the shallow trench isolation (STI) structure 45 is formed, thereby constructing the ESD protection circuit 3. In this embodiment, the gate structure 40, source structure 41 and bulk structure 43 are all electrically connected to Vss or grounded, the drain structure 42 is electrically connected to the I/O pad 30, and the guard ring 44 shares the low voltage V_{dd}_{_{—}}_{low}, e.g. 5 volts, with the second sub-circuit 48. The second sub-circuit 48, for example, is a digital logic circuits. The configuration still exhibits latch-up diminishing capability while maintaining the tolerance to the current flow from the I/O pad 30 to the drain 42 at the level of about 500 mA.

Managing the reverse bias to the PN junction between the high voltage N-well region 441 and the grounded P well 431 at a reasonably low level facilitates the reduction of power consumption, thereby improving the tolerance of the ESD protection circuit with a guard ring to a high voltage or large current.

It is to be noted that according to the present invention, when more than two working voltages are involved, the guard ring can be coupled to any of the working voltages higher than Vss, except the highest one. For example, if the IC chip uses working voltages of 60V, 12V and 5V, the guard ring according to the present invention is preferably coupled to the lower voltage 12V or 5V.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. An electrostatic discharge protection circuit for use in an integrated circuit, the integrated circuit including a first sub-circuit and a second sub-circuit, wherein the first sub-circuit is coupled to a first working voltage, the second sub-circuit is coupled to a second working voltage, and the second working voltage is lower than the first working voltage, the electrostatic discharge protection circuit comprising:
a first metal-oxide-semiconductor transistor of a first conductive type, having a first drain thereof electrically connected to a pad of the integrated circuit, and a first gate, a first source and a first bulk thereof electrically connected to a bulk voltage;
a guard ring of the first conductive type, surrounding the first metal-oxide-semiconductor transistor of the first conductive type and coupled to the second working voltage source; and
a second metal-oxide-semiconductor transistor of the first conductive type, having a second drain thereof electrically connected to the first working voltage, and a second gate and a second source thereof electrically connected to the pad.

2. (canceled)

3. The electrostatic discharge protection circuit according to claim 2, wherein each of the first and second metal-oxide-semiconductor transistors of the first conductive type is a lateral diffused N-channel metal-oxide-semiconductor field effect transistor.

4. The electrostatic discharge protection circuit according to claim 3, wherein the guard ring includes a N well region and a doped N-type region having a doping concentration substantially greater than that of the N well region.

5. The electrostatic discharge protection circuit according to claim 1, further comprising a shallow trench isolation structure between the guard ring and the first metal-oxide-semiconductor transistors of the first conductive type.

6. The electrostatic discharge protection circuit according to claim 1, wherein the first sub-circuit is coupled with a working voltage higher than that coupled with the second sub-circuit, and the second sub-circuit is a digital logic circuit.

7. The electrostatic discharge protection circuit according to claim 1, wherein the second working voltage is smaller than the first working voltage but higher than a third working voltage used in the integrated circuit.

8. The electrostatic discharge protection circuit according to claim 7, wherein the first working voltage, the second working voltage and the third working voltage are 60V, 12V and 5V, respectively.

9. (canceled)

10. (canceled)
